(19) United States
(12) Patent Application Publication
(10) Pub. No.: US 2025/0194239 A1
(43) Pub. Date: Jun. 12, 2025

(54) INVERTER AND SEMICONDUCTOR INTEGRATED CIRCUIT DEVICE INCLUDING THE INVERTER

(71) Applicant: SK hynix Inc., Icheon-si Gyeonggi-do (KR)

(72) Inventors: Hyeong Jun KWON, Icheon-si Gyeonggi-do (KR); Jae Ho KIM, Icheon-si Gyeonggi-do (KR)

(73) Assignee: SK hynix Inc., Icheon-si Gyeonggi-do (KR)

(21) Appl. No.: 18/611,218

(22) Filed: Mar. 20, 2024

(30) Foreign Application Priority Data
Dec. 12, 2023 (KR) 10-2023-0180013

(51) Int. Cl. H01L 27/092; H01L 23/528; H01L 29/08; H01L 29/417; H03K 3/037; H03K 5/134

(52) U.S. Cl. CPC H10D 84/85; H01L 23/5286; H03K 3/037; H10D 62/151; H10D 64/257; H03K 5/134

(57) ABSTRACT

An inverter including at least one PMOS transistor and at least one NMOS transistor. The PMOS transistor including a first gate, a first source and a first drain. The first gate may be connected to an input signal line. The first source may be connected to a power voltage line. The first drain may be connected to an output signal line. The NMOS transistor including a second gate, a second source and a second drain. The second gate may be connected to the input signal line. The second source may be connected to a ground voltage line. The second drain may be connected to the output signal line.

### CROSS-REFERENCES TO RELATED APPLICATION

The present application claims priority under 35 U.S.C. § 119(a) to Korean Patent application number 10-2023-0180013, filed on Dec. 12, 2023, in the Korean Intellectual Property Office, which is incorporated herein by reference in its entirety.

### BACKGROUND

### 1. Technical Field

Various embodiments generally relate to an inverter and a semiconductor integrated circuit device including the same, more particularly, to an inverter having output current characteristics and a semiconductor integrated circuit device including the inverter.

### 2. Related Art

A semiconductor integrated circuit device may use an inverter. The inverter may invert a signal.

Further, the inverter may be used as a buffer circuit. The inverter may be used as a delay circuit. The buffer circuit may include a plurality of the inverters serially connected with each other. The delay circuit may delay the input signal for a duration of time.

### SUMMARY

In an embodiment, an inverter may include at least one PMOS transistor including a first gate connected to an input signal line, a first source connected to a power voltage line and a first drain connected to an output signal line; and at least one NMOS transistor including a second gate connected to the input signal line, a second source connected to a ground voltage line and a second drain connected to the output signal line. In an embodiment, at least one of the first source and the second source has a single finger region extended in a first direction, and at least one of the first drain and the second drain has a multi finger region extended substantially parallel to each other in a second direction different from the first direction.

In an embodiment, an inverter may include a plurality of sub-PMOS transistors, each of the sub-PMOS transistors including a first gate extended in a first direction, a first source positioned at one side of the first gate, and a plurality of first drains positioned at the other side of the first gate and parallely extended in a second direction intersected with first direction, a plurality of sub-NMOS transistors, each of the sub-NMOS transistors including a second gate extended in the first direction, a second source positioned at one side of the second gate, and a plurality of second drains positioned at the other side of the second gate and parallely extended in the second direction, an input signal line commonly connected to the first gate and the second gate, a power voltage line electrically connected to the first source, a ground voltage line electrically connected to the second source, and an output signal line commonly connected to the first drains and the second drains.

In an embodiment, a semiconductor integrated circuit device may include a first inverter, and a second inverted serially connected with the first inverter. In an embodiment, at least one first inverter and the second inverter comprises at least one PMOS transistor and at least one NMOS transistor. In an embodiment, the PMOS transistor may include a first gate extended in a first direction, a first source positioned at one side of the first gate, and a plurality of first drains positioned at the other side of the first gate and parallely extended in a second direction intersected with first direction. In an embodiment, the NMOS transistor may include a second gate extended in the first direction, a second source positioned at one side of the second gate, and a plurality of second drains positioned at the other side of the second gate and parallely extended in the second direction.

### BRIEF DESCRIPTION OF THE DRAWINGS

The above and another aspects, features and advantages

of the subject matter of the present disclosure will be more clearly understood from the following detailed description taken in conjunction with the accompanying drawings, in which:

FIG. 1 is a block diagram illustrating an inverter in accordance with embodiments;

FIG. 2 is a circuit diagram illustrating the inverter in FIG. 1;

FIG. 3 is a layout illustrating an inverter in accordance with embodiments;

FIG. 4 is an equivalent circuit diagram between a power voltage line and an output signal line in an inverter in accordance with embodiments;

FIG. 5 is an equivalent circuit diagram between an output signal line and a ground voltage line in an inverter in accordance with embodiments;

FIGS. 6, 7, 8, 9, and 10 are layouts illustrating a method of forming an inverter in accordance with embodiments;

FIG. 11 is a circuit diagram illustrating an inverter in accordance with embodiments;

FIG. 12 is a layout illustrating the inverter in FIG. 11;

FIG. 13 is a circuit diagram illustrating an inverter in accordance with embodiments;

FIG. 14 is a circuit diagram illustrating a semiconductor integrated circuit device with a plurality of inverters in accordance with embodiments; and

FIG. 15 is a layout illustrating the semiconductor integrated circuit device in FIG. 14.

### DETAILED DESCRIPTION

Various embodiments of the present disclosure will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present disclosure as defined in the appended claims.

The present disclosure is described herein with reference to cross-section and/or plan illustrations of idealized embodiments of the present disclosure. However, embodiments of the present disclosure should not be construed as limiting the concepts. Although a few embodiments of the present disclosure will be shown and described, it will be appreciated by those of ordinary skill in the art that changes may be made in these embodiments without departing from the principles and spirit of the present disclosure.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, spatially relative terms, such as “beneath,” “below,” “bottom,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the phrase “coupled to” and “connected to” refer to structures operatively connected with each other, such as electrically connected through a direct Ohmic connection or through an indirect connection (e.g., by way of another structure).

An inverter may be used in various circuits of a semiconductor integrated circuit device. The inverter may invert an input signal. The inverter may include a CMOS inverter with an NMOS transistor and a PMOS transistor.

Further, the inverter may be used as a buffer circuit and a delay circuit, for example, a ring oscillator. The buffer circuit may include a plurality of the inverters serially connected with each other (hereinafter, referred to as an inverter chain structure) to buffer the input signal to a constant voltage level. The delay circuit may delay the input signal for a time.

It may be required to provide the semiconductor integrated circuit device with the inverter chain structure such as the delay circuit and the oscillator with a small occupying area and an effective output current characteristic.

Various embodiments provide an inverter having an improved output current characteristic.

Various embodiments may provide a semiconductor integrated circuit device including an inverter.

According to embodiments, there may be provided an inverter including at least one PMOS transistor and at least one NMOS transistor.

In an embodiment, the PMOS transistor may include a first gate, a first source and a first drain. The first gate may be connected to an input signal line. The first source may be connected to a power voltage line. The first drain may be connected to an output signal line.

In an embodiment, the NMOS transistor may include a second gate, a second source and a second drain. The second gate may be connected to the input signal line. The second source may be connected to a ground voltage line. The second drain may be connected to the output signal line.

In an embodiment, at least one of the first source and the second source may be formed in an active region having a single finger shape extended in a first direction. In an embodiment, at least one of the first drain and the second drain may be formed in an active region having a multiple finger shape extended parallel to each other in a second direction different from the first direction.

According to various embodiments, there may be provided an inverter. The inverter may include a plurality of sub-PMOS transistors, a plurality of sub-NMOS transistors, an input signal line, a power voltage line, a ground voltage line and an output signal line.

In an embodiment, each of the sub-PMOS transistors may include a first gate, a first source and a plurality of first drains. In an embodiment, the first gate may be extended in a first direction. The first source may be arranged at one side of the first gate. In an embodiment, the first drains may be arranged at the other side of the first gate. In an embodiment, the first drains may be extended in a second direction intersected with the first direction.

In an embodiment, each of the sub-NMOS transistors may include a second gate, a second source and a plurality of second drains. In an embodiment, the second gate may be extended in the first direction. In an embodiment, the second source may be arranged at one side of the second gate. In an embodiment, the second drains may be arranged at the other side of the second gate. In an embodiment, the second drains may be extended parallel to each other in the second direction.

In an embodiment, the input signal line may be commonly connected to the first gate and the second gate. In an embodiment, the ground voltage line may be commonly connected to the first source. The power voltage line may be connected to the second source.

In an embodiment, the sub-PMOS transistors may include a first sub-PMOS transistor and a second sub-PMOS transistor. In an embodiment, the first drains of the first sub-PMOS transistor and the second drains of the second sub-PMOS transistor may be alternately arranged parallel to each other.

In an embodiment, the sub-NMOS transistors may include a first sub-NMOS transistor and a second sub-NMOS transistor. In an embodiment, the second drains of the first sub-NMOS transistor and the second drains of the second sub-NMOS transistor may be alternately arranged parallel to each other.

According to embodiments, there may be provided a semiconductor integrated circuit device. In an embodiment, the semiconductor integrated circuit device may include a first inverter and a second inverter serially connected with each other. In an embodiment, at least one of the first inverter and the second inverter may include a PMOS transistor and an NMOS transistor.

In an embodiment, the PMOS transistor may include a first gate, a first source and a plurality of first drains. In an embodiment, the first gate may be extended in a first direction. In an embodiment, the first source may be arranged at one side of the first gate. In an embodiment, the first drains may be arranged at the other side of the first gate. In an embodiment, the first drains may be extended in a second direction intersected with the first direction.

In an embodiment, the NMOS transistor may include a second gate, a second source and a plurality of second drains. In an embodiment, the second gate may be extended in the first direction. In an embodiment, the second source may be arranged at one side of the second gate. In an embodiment, the second drains may be arranged at the other side of the second gate. In an embodiment, the second drains may be extended parallel to each other in the second direction.

In an embodiment, each of the first inverter and the second inverter may include the PMOS transistor and the NMOS transistor. In an embodiment, the semiconductor integrated circuit device may include a first input signal line, a first output signal line, a second input signal line and a second output signal line.

In an embodiment, the first input signal line may be connected to the first and second gates of the first inverter to receive an input signal.

In an embodiment, the first output signal line may be commonly connected the first and second drains of the first inverter.

In an embodiment, the second input signal line may be connected to the first and second gates of the second inverter. In an embodiment, the second input signal line may be electrically connected with the first output signal line.

In an embodiment, the second output signal line may be commonly connected to the first and second drains of the second inverter.

According to embodiments, each of the PMOS transistor and the NMOS transistor may include the source having the single finger shape or a single pattern shape with an area and the drain having the multi finger shape or a multi pattern shape extended parallel to each other.

In an embodiment, the PMOS transistor and the NMOS transistor may include the plurality of the drains as an output node of the inverter to improve the output current characteristic.

Further, in an embodiment, the sources of the PMOS transistor and the NMOS transistor to which a power voltage and a ground voltage may be input may have an area larger than a summed area of the drains to reduce a voltage loss caused by a high contact resistance.

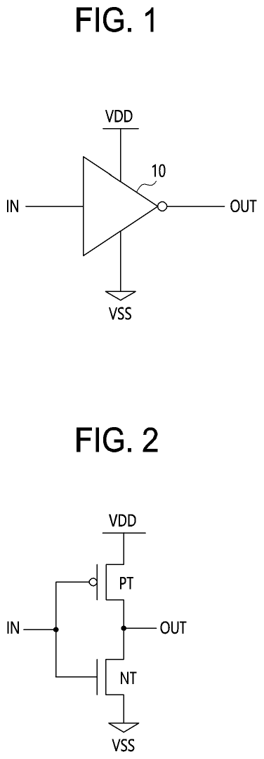

FIG. 1 is a block diagram illustrating an inverter in accordance with various embodiments and FIG. 2 is a circuit diagram illustrating the inverter in FIG. 1.

Referring to FIGS. 1 and 2, an inverter 10 of various embodiments may be connected between a power voltage line VDD and a ground voltage line VSS. The inverter 10 may receive an input signal to output an inverted input signal as an output signal.

The inverter 10 may include at least one p-channel metal-oxide semiconductor (PMOS) transistor PT and at least one n-channel metal-oxide semiconductor (NMOS) transistor NT.

The PMOS transistor PT may be connected between the power voltage line VDD and an output signal line OUT. The PMOS transistor PT may include a gate, a source and a drain. The gate of the

PMOS transistor PT may be electrically connected with an input signal line IN. The source of the PMOS transistor PT may be connected with the power voltage line VDD. The drain of the PMOS transistor PT may be electrically connected with an output signal line OUT.

The NMOS transistor NT may be connected between the output signal line OUT and the ground voltage line VSS. The NMOS transistor NT may include a gate, a source and a drain. The gate of the NMOS transistor NT may be electrically connected with the input signal line IN. The source of the NMOS transistor NT may be electrically connected with the ground voltage line VSS. The drain of the NMOS transistor NT may be electrically connected with the output signal line OUT.

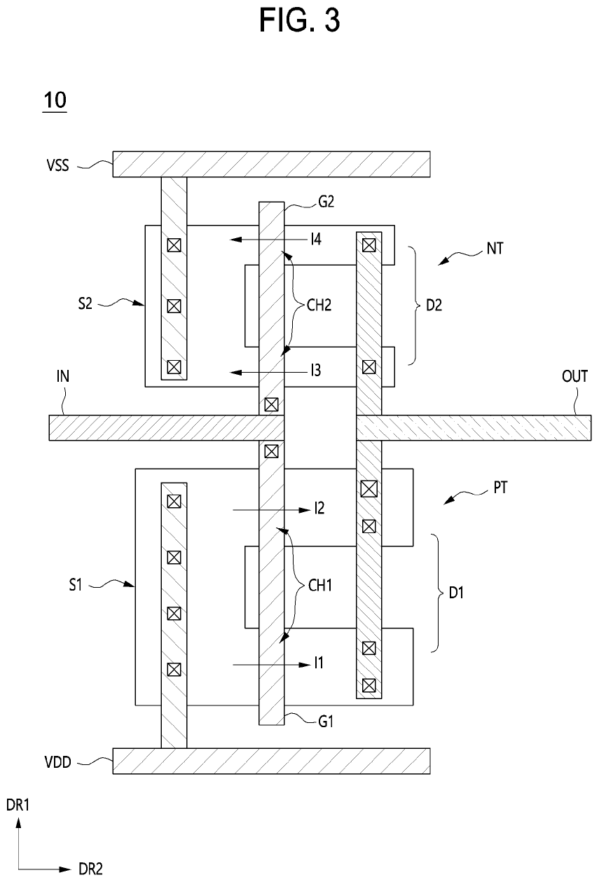

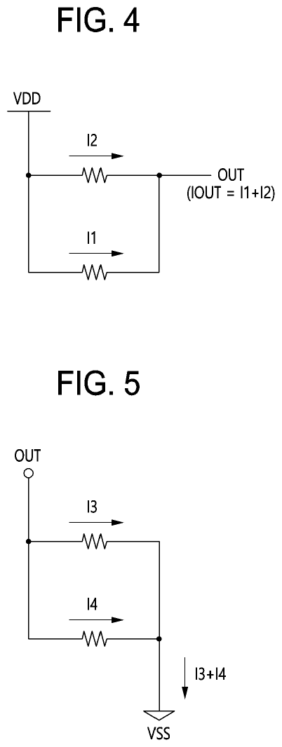

FIG. 3 is a layout illustrating an inverter in accordance with various embodiments, FIG. 4 is an equivalent circuit diagram between a power voltage line and an output signal line in an inverter in accordance with various embodiments and FIG. 5 is an equivalent circuit diagram between an output signal line and a ground voltage line in an inverter in accordance with various embodiments.

Referring to FIG. 3, the PMOS transistor PT and the NMOS transistor NT in the inverter 10 may be arranged side by side spaced apart from each other by a uniform gap along a first direction DR1.

Hereinafter, the gate, the source and the drain in the PMOS transistor PT may be referred to as a first gate G1, a first source S1 and a first drain D1, respectively. The gate, the source and the drain in the NMOS transistor NT may be referred to as a second gate G2, a second source S2 and a second drain D2, respectively.

The first gate G1 may be extended in the first direction DR1. The first source S1 may be positioned at one side of the first gate G1. The first drain D1 may be positioned at the other side of the first gate G1. The first source S1 may have a single finger shape or a single pattern shape. The first source S1 may be extended in the first direction DR1. The first drain D1 may have a multi finger shape or a multi pattern shape extended parallel to each other along a second direction DR2 intersected with the first direction DR1. That is, the first drain D1 may be inclined to the first source S1 at an angle, for example, about 90°. Further, first channel region CH1 of the PMOS transistor PT may be positioned between the first source S1 and the first drains D1. The first channel region CH1 may have a structure corresponding to a structure of the first drains D1. The first channel region CH1 may be branched from a side surface of the first source S1.

The second gate G2 of the NMOS transistor NT may be extended in the first direction DR1. In order to connect the second gate G2 with the first gate G1, the second gate G2 and the first gate G1 may be arranged side by side. Each of the first gate G1 and the second gate G2 may include a single line. The second source S2 may be arranged at the one side of the second gate G2. The second drain D2 may be arranged at the other side of the second gate G2.

The second gate G2 may have a single finger shape extended in the first direction DR1. The second drain D2 may have a multi finger shape extended parallel to each other along the second direction DR2. In various embodiments, numbers of the first drains D1 may be substantially equal to or different from numbers of the second drains D2. A second channel region CH2 of the NMOS transistor NT may be positioned between the second source S2 and the second drain D2. The second channel region CH2 may have a structure corresponding to a structure of the second drain D2. The second channel region CH2 may be extended from the second source S2.

Therefore, the PMOS transistor PT may include one first source S1 and the plurality of first drains D1 and the NMOS transistor NT may include one second source S2 and the plurality of second drains D2.

The first gate G1 and the second gate G2 may be electrically connected with the input signal line IN.

The first drains D1 and the second drains D2 may be commonly connected to the output signal line OUT.

The first source S1 may be electrically connected with the power voltage line VDD. The second source S2 may be electrically connected with the ground voltage line VSS.

For example, when an input signal having a logic low is transmitted through the input signal line IN, the PMOS transistor PT may be turned-on and the NMOS transistor NT may be turned-off.

As shown in FIG. 4, parallel current paths I1 and I2 may be generated between the power voltage line VDD and the output signal line OUT in the inverter 10. Thus, an output current IOUT of the inverter 10 may be a sum (IOUT=I1+I2) of the parallel current paths.

When a signal having a logic high may be transmitted through the input signal line IN, the PMOS transistor PT may be turned-off and the NMOS transistor NT may be turned-on.

As shown in FIG. 5, parallel current paths I3 and I4 may be generated between the output signal line OUT and the ground voltage line VSS in the inverter 10. Thus, charges in the first and second drains D1 and D2 may be discharged to the ground voltage line VSS through the parallel current paths I3 and I4.

According to various embodiments, the first drain D1 of the PMOS transistor PT and the second drain D2 of the NMOS transistor NT connected to the output signal line OUT may have the multi pattern shape. Thus, in an embodiment, the numbers of the current paths between the output signal line OUT of the PMOS transistor PT and the output signal line OUT of the NMOS transistor NT may be increased to improve an output current characteristic of the inverter 10.

Particularly, the total area of the first drain D1 may be less than an area of the first source S1. The total area of the second drain D2 may also be smaller than an area of the second source S2. Thus, in an embodiment, a drain junction capacitance for determining the output current characteristic of the inverter 10 may be greatly reduced to additionally improve the output current characteristic of the inverter 10.

Further, the area of the first source S1 of the PMOS transistor PT, which may make contact with the power voltage line VDD, may be larger than the total area of the first drain D1. Furthermore, the area of the second source S2 of the NMOS transistor NT, which may make contact with the ground voltage line VSS, may be larger than the total area of the second drain D2. Thus, in an embodiment, a contact resistance between the first source S1 and the power voltage line VDD and a contact resistance between the second source S2 and the ground voltage line VSS may be secured to improve an on-current characteristic of the inverter 10. That is, in an embodiment, the voltage loss caused by the contact resistance may be decreased to improve the on-current characteristic.

Moreover, in an embodiment, the channel regions CH1 (areas between the first source S1 and the first drains D1 and overlapping with the first gate G1) of the PMOS transistor PT may be branched into the first channel regions CH1 to improve an off-current characteristic of the PMOS transistor PT. The channel regions CH2 (areas between the second source S2 and the second drains D2 and overlapping with the second gate G2) of the NMOS transistor NT may be branched into the second channel region CH2 to improve an off-current characteristic of the NMOS transistor NT.

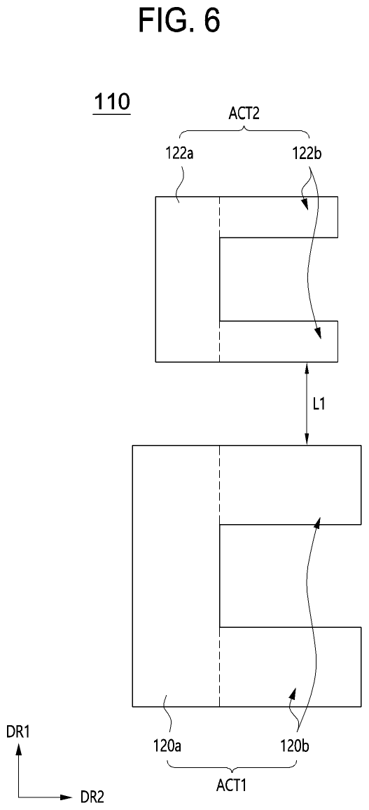

FIGS. 6 to 10 are layouts illustrating a method of forming an inverter in accordance with various embodiments.

Referring to FIG. 6, an isolation layer 110 may be formed in a substrate to define a first active region ACT1 and a second active region ACT2.

The first active region ACT1 and the second active region ACT2 may be arranged side by side along a first direction DR1. For example, the first active region ACT1 and the second active region ACT2 may be spaced apart from each other by a length L1. The length L1 may be a minimum length for securing electrical characteristics of a PMOS transistor PT and an NMOS transistor NT. The first active region ACT1 may include an n-well at which the PMOS transistor PT may be to be formed. The second active region ACT2 may include a p-well at which the NMOS transistor NT may be to be formed.

Generally, when a mobility difference between a majority carrier of the NMOS transistor NT and a majority carrier of the PMOS transistor PT may be considered, an area of the PMOS transistor PT may be larger than an area of the NMOS transistor NT in forming an inverter 10. Thus, an area of the first active region ACT1 for the PMOS transistor PT may be larger than an area of the second active region ACT2 for the NMOS transistor NT.

The first active region ACT1 may include a first single finger region 120a and a first multi finger region 120b. For example, the first single finger region 120a may be extended by a first length along the first direction DR1. The first length may correspond to a channel width of the PMOS transistor PT. The first multi finger region 120b may be extended parallel to each other from a side surface of the first single finger region 120a along a second direction DR2. The first multi finger regions 120b may be spaced apart from each other by a uniform gap.

The second active region ACT2 may include a second single finger region 122a and a second multi finger region 122b. For example, the second single finger region 122a may be extended by a second length along the first direction DR1. The second length may correspond to a channel width of the NMOS transistor NT. The second multi finger region 122b may be extended parallel to each other from a side surface of the second single finger region 122a along the second direction DR2. The second multi finger regions 1202 may be spaced apart from each other by a uniform gap. Further, numbers of the second multi finger regions 122b may be substantially equal to or different from numbers of the first multi finger regions 120b. The numbers of the first multi finger regions 120b and the second multi finger regions 122b may be changed in accordance with characteristics and layout areas of the inverter 10.

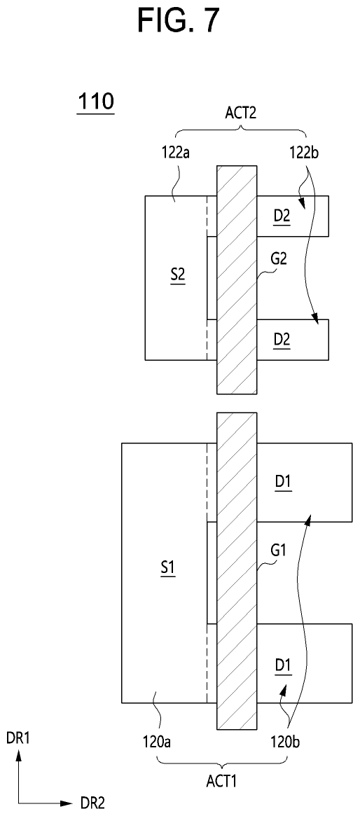

Referring to FIG. 7, a first gate G1 may be arranged on the first active region ACT1. A second gate G2 may be arranged on the second active region ACT2.

The first gate G1 may be arranged at a central portion of the first active region ACT1 along the first direction DR1. For example, the first gate G1 may be extended longer than a length of the first direction DR1 of the first active region ACT1. By forming the first gate G1, the first active region ACT1 may be divided into two regions with respect to the first gate G1. The first single finger region 120a at one side of the first gate G1 may be a region where a source of the PMOS transistor PT may be formed. The first multi finger region 120b at the other side of the first gate G1 may be a region where a drain of the PMOS transistor PT may be formed.

P type impurities may be implanted into the regions where the source of the PMOS transistor and the drain of the PMOS transistor may be formed to form a first source S1 of the PMOS transistor and a first drain D1 of the PMOS transistor. The first multi finger region 120b overlapped with the first gate G1 may be a first channel region CH1 of the PMOS transistor.

The first source S1 may have a single finger shape or a single pattern shape extended in the first direction DR1. The first drain D1 may have a single finger shape or a single pattern shape extended in the second direction DR2. For example, as shown in FIG. 7, a first protrusion (i.e., first-first drain D1) may protrude from the first source S1 in the second direction DR2 and a second protrusion (i.e., second-first drain D1) may also protrude from the first source S1 in the second direction DR2. For example, the first protrusion (i.e., first-first drain D1) and the second protrusion (i.e., second-first drain D1) may be spaced apart from each other in the first direction DR1. For example, the first protrusion (i.e., first-first drain D1) and the second protrusion (i.e., second-first drain D1) may both extend in the second direction DR2 in parallel to each other. In an embodiment, as shown in FIG. 7, a multi finger shape may include two or more protrusions included in the first drain D1 extending in the second direction DR2 in parallel with one another from the first source S1.

The second gate G2 may be arranged at a central portion of the second active region ACT2 along the first direction DR1. For example, the second gate G2 may be extended longer than a length of the first direction DR1 of the second active region ACT2. The second gate G2 may have a width substantially equal to or different from a width of the first gate G1. By forming the second gate G2, the second active region ACT2 may be divided into two regions with respect to the second gate G2. The second single finger region 122a at one side of the second gate G2 may be a region where a source of the NMOS transistor may be formed. The second multi finger region 122b at the other side of the second gate G2 may be a region where a drain of the NMOS transistor may be formed.

N type impurities may be implanted into the regions where the source of the NMOS transistor and the drain of the NMOS transistor may be formed to form a second source S2 of the NMOS transistor and a second drain D2 of the NMOS transistor. The second multi finger region 122b overlapped with the second gate G2 may be a channel region CH2 of the NMOS transistor.

The second source S2 may have a single finger shape or a single pattern shape extended in the first direction DR1. The second drain D2 may have a single finger shape or a single pattern shape extended in the second direction DR2. For example, as shown in FIG. 7, a first protrusion (i.e., first-second drain D2) may protrude from the second source S2 in the second direction DR2 and a second protrusion (i.e., second-second drain D2) may also protrude from the second source S2 in the second direction DR2. For example, the first protrusion (i.e., first-second drain D2) and the second protrusion (i.e., second-second drain D2) may be spaced apart from each other in the first direction DR1. For example, the first protrusion (i.e, first-second drain D2) and the second protrusion (i.e., second-second drain D2) may both extend in the second direction DR2 in parallel to each other. In an embodiment, as shown in FIG. 7, a multi finger shape may include two or more protrusions included in the second drain D2 extending in the second direction DR2 in parallel with one another from the second source S2.

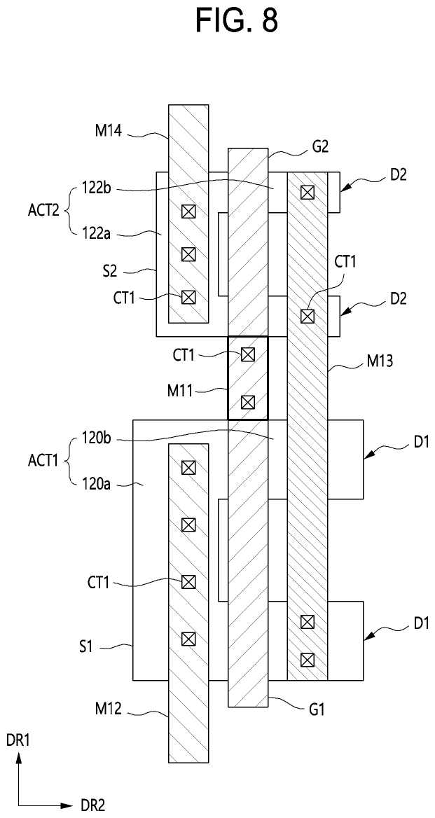

Referring to FIG. 8, first interconnection lines M11-M14 may be formed on the first active region ACT1 and the second active region ACT2. For example, a first insulating interlayer may be interposed between the first and second active regions ACT1 and ACT2 and the first interconnection lines M11-M14.

The first interconnection line M11 may be connected between the first gate G1 and the second gate G2 using at least one first contact CT1.

The first interconnection line M12 may be electrically connected with the first source S1 through the at least one first contact CT1. The first interconnection line M12 may be extended in the first direction DR1.

The first interconnection line M13 may be electrically connected between the first drains D1 and the second drains D2 using a plurality of the first contacts CT1. The first interconnection line M13 may be extended in the first direction DR1. In various embodiments, the first drains D1 and the second drains D2 may be connected with each other through a single first interconnection line M13. Alternatively, the first drains D1 and the second drains D2 may be connected with each other through multiple single interconnection lines.

The first interconnection line M14 may be connected with the second drains D2 using the first contacts CT1. The first interconnection line M14 may be extended in the first direction DR1.

The first contacts CT1 may be formed through the first insulating interlayer. The first contacts CT1 may be electrically connected between conductive regions under the first insulation interlayer, for example, the first and second active regions ACT1 and ACT2 and the first and second gate G1 and G2 and the first interconnection lines M11-M14 on the first insulating interlayer.

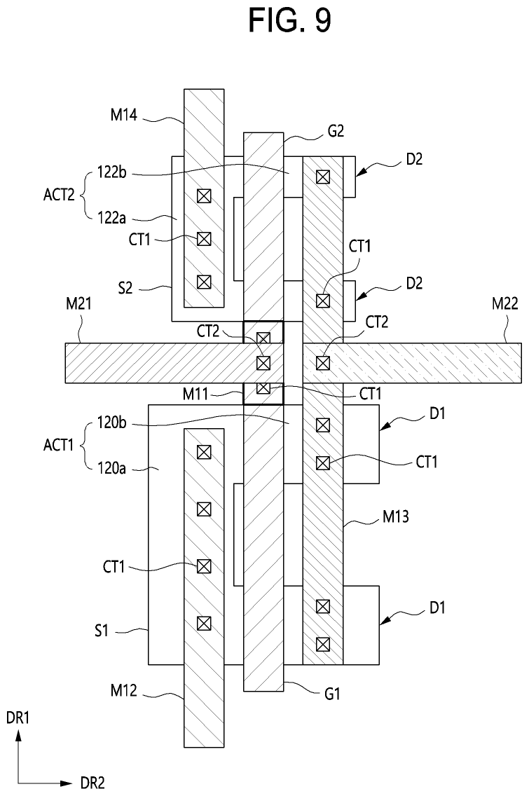

Referring to FIG. 9, second interconnection lines M21 and M22 may be formed on the first interconnection lines M11-M14. A second insulating interlayer (not shown) may be interposed between the first interconnection lines M11-M14 and the second interconnection lines M21 and M22.

The second interconnection line M21 may be electrically connected with the first interconnection line M11 using at least one second contact CT2. The second interconnection line M21 may be extended in the second direction DR2. The second interconnection line M21 may be used for an input signal line of the inverter.

The second interconnection line M22 may be electrically connected with the first interconnection line M13 using the second contact CT2. The second interconnection line M22 may be extended in the second direction DR2. The second interconnection line M22 may be used for an output signal line of the inverter.

The second contacts CT2 may be formed through the second insulating interlayer. The second contacts CT2 may be electrically connected between the first interconnection lines M11 and M13 under the second insulating interlayer and the second interconnection lines M21 and M22 over the second insulating interlayer.

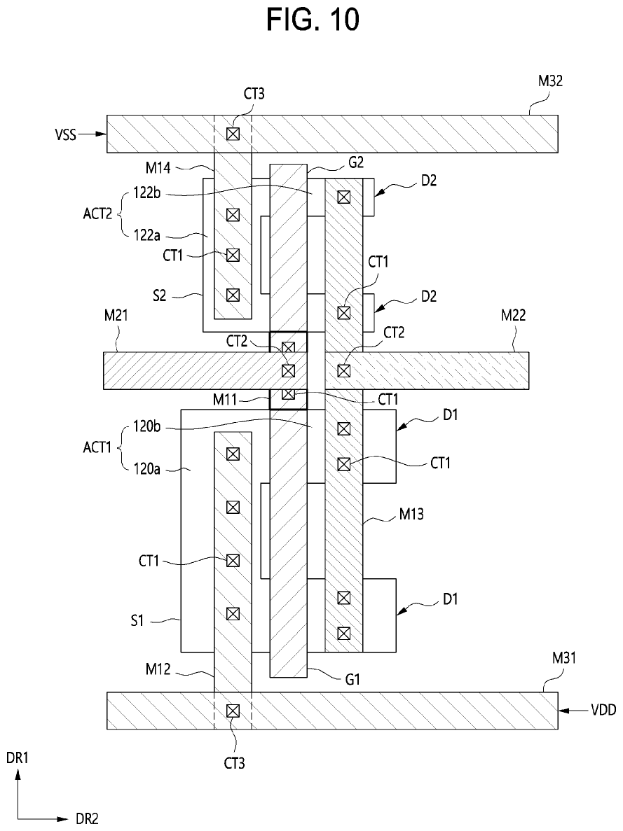

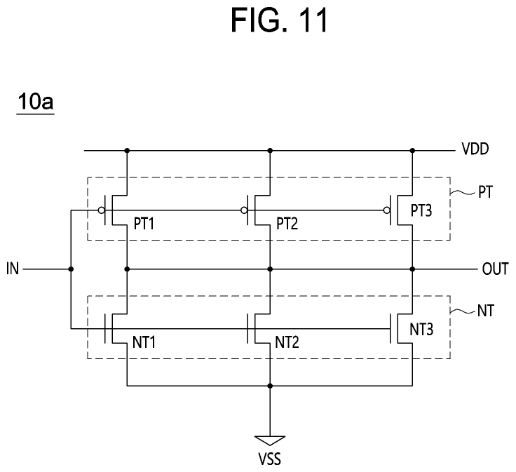

Referring to FIG. 10, third interconnection lines M31 and M32 may be formed over a third insulating interlayer (not shown) which is formed over the second interconnection lines M21 and M22. For example, the third insulating interlayer may be interposed between the second interconnection lines M21 and M22 and the third interconnection lines M31 and M32.

The third interconnection line M31 may be electrically connected with the first interconnection line M12 using at least one third contact CT3. The third interconnection line M31 may be extended in the second direction DR2. The third interconnection line M31 may be used for a power voltage line VDD. Thus, a power voltage may be transmitted to the first source S1 through the third interconnection line M31, the third contact CT3, the first interconnection line M12 and the first contact CT1.

The third interconnection line M32 may be electrically connected with the first interconnection lime M14 using the third contact CT3. The third interconnection line M32 may be extended in the second direction DR2. The third interconnection lime M32 may be used for a ground voltage line VSS. Thus, a ground voltage may be transmitted to the second source S2 through the third interconnection line M32, the third contact CT3, the first interconnection line M14 and the first contact CT1.

The third contact CT3 may be formed through the second and third insulating interlayers. The third contact CT3 may be electrically connected between the first interconnection lines M12 and M14 under the second insulating interlayer and the third interconnection lines M31 and M32 over the third insulating interlayer.

Alternatively, without forming the third interconnection lines, as shown in FIG. 3, the power voltage line VDD and the ground voltage line VSS may be the second interconnection lines M21 and M22. Further, although not depicted in drawings, at least one of the first to third insulating interlayers may have a structure including stacked insulation layers. Further, an additional interconnection line may be formed in the stacked insulation layers.

Structures and positions of the first to third interconnection lines M11-M14, M21-M22 and M31-M32 and positions of the contacts CT1, CT2 and CT3 may be changed in accordance with a designer.

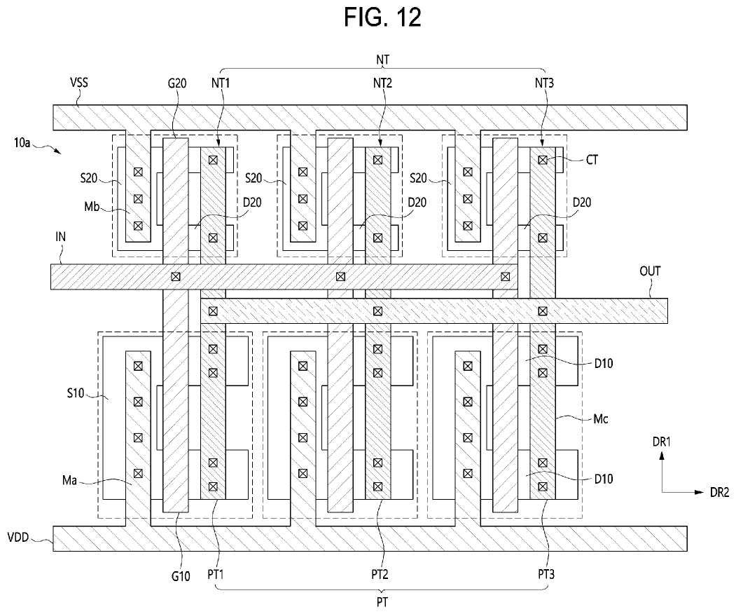

FIG. 11 is a circuit diagram illustrating an inverter in accordance with various embodiments and FIG. 12 is a layout illustrating the inverter in FIG. 12.

Referring to FIGS. 11 and 12, in an embodiment, a PMOS transistor PT and an NMOS transistor NT in an inverter 10a may be fingered into a plurality of sub-PMOS transistors PT1, PT2 and PT3 and a plurality of sub-NMOS transistors NT1, NT2 and NT3 to improve layout efficiency and to reduce a gate resistance.

The sub-PMOS transistors PT1, PT2 and PT3 may be parallely arranged between a power voltage line VDD and an output signal line OUT. For example, as shown in FIG. 12 the sub-PMOS transistors PT1, PT2 and PT3 are electrically connected in parallel between the power voltage line VDD and the output signal line OUT. For example, the physical location of the sub-PMOS transistors PT1, PT2 and PT3 may be arranged in parallel to each other between a power voltage line VDD and an output signal line OUT as shown in FIG. 12. The sub-NMOS transistors NT1, NT2 and NT3 may be parallely arranged between the output signal line OUT and a ground voltage line VSS. For example, as shown in FIG. 12, the sub-NMOS transistors NT1, NT2 and NT3 may be electrically connected in parallel between the output signal line OUT and a ground voltage line VSS. For example, the physical location of the sub-NMOS transistors NT1, NT2 and NT3 may be arranged in parallel to each other between the output signal line OUT and a ground voltage line VSS.

The structure of the PMOS transistor PT in FIG. 3 may be downsized to form a structure of the sub-PMOS transistors PT1, PT2 and PT3. For example, a total drive force of the sub-PMOS transistors PT1, PT2 and PT3 may be substantially the same as a drive force of the PMOS transistor PT in FIG. 3. The structure of the NMOS transistor NT in FIG. 3 may be downsized to form a structure of the sub-NMOS transistors NT1, NT2 and NT3. For example, a total drive force of the sub-NMOS transistors NT1, NT2 and NT3 may be substantially the same as a drive force of the NMOS transistor NT in FIG. 3.

In various embodiments, first gates G10 of the sub-PMOS transistors PT1, PT2 and PT3 and second gates G20 of the sub-NMOS transistors NT1, NT2 and NT3 corresponding to the first gates G10 may include the individual conductive line in FIG. 3, or a single conductive line. The first gates G10 and the second gates G20 may be commonly connected to an input signal line IN.

Each of first sources S10 of the sub-PMOS transistors PT1, PT2 and PT3 may be electrically connected with the power voltage line VDD via interconnection lines Ma.

Each of second sources S20 of the sub-NMOS transistors NT1, NT2 and NT3 may be electrically connected with the ground voltage line VSS via interconnection lines Mb.

First drains D10 of the sub-PMOS transistors PT1, PT2 and PT3 may be connected with second drains D20 of the sub-NMOS transistors NT1, NT2 and NT3 facing the first drains D10 by interconnection lines Mc. Further, the interconnection lines Mc may be commonly connected to the output signal line OUT.

The interconnection lines Ma, Mb and Mc, the input signal line IN, the output signal line OUT, the power voltage line VDD and the ground voltage line VSS may be positioned on the same plane or on different planes.

In various embodiments, when at least one portion of the interconnection lines Ma, Mb and Mc, the input signal line IN, the output signal line OUT, the power voltage line VDD and the ground voltage line VSS is overlapped with each other, if a contact CT exists in the overlapped portion, the overlapped two conductive lines may be electrically connected with each other. In contrast, if the contact CT does not exist in the overlapped portion, the overlapped two conductive lines may be electrically isolated from each other.

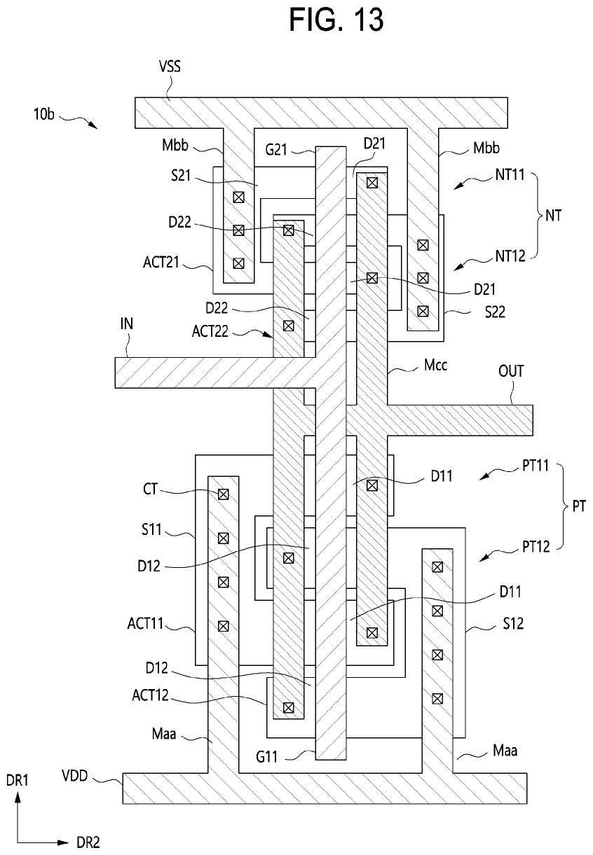

FIG. 13 is a circuit diagram illustrating an inverter in accordance with various embodiments.

Referring to FIG. 13, a PMOS transistor PT of an inverter 10b may be fingered into first and second sub-PMOS transistors PT11 and PT12. An NMOS transistor NT of the inverter 10b may be fingered into first and second sub-NMOS transistors NT11 and NT12. The structure of the PMOS transistor PT in FIG. 3 may be downsized to form a structure of each of the first and second sub-PMOS transistors PT11 and PT12. The structure of the NMOS transistor NT in FIG. 3 may be downsized to form a structure of each of the first and second sub-NMOS transistors NT11 and NT12.

The first sub-PMOS transistor PT11 may include a first source S11 and a plurality of first drains D11. The second sub-PMOS transistors PT12 may include a first source S12 and a plurality of first drains D12. In various embodiments, the first drain D12 of the second sub-PMOS transistor PT12 may be inserted into a space between the adjacent first drains D11 of the first sub-PMOS transistor PT11. Thus, an active region ACT11 of the first sub-PMOS transistor PT11 and an active region ACT12 of the second sub-PMOS transistor PT12 may be symmetrical with respect to the first direction DR1 at an angle of about 180° to alternately arrange the first drains D11 and D12 parallel to each other. By the arrangement of the active regions ACT11 and ACT12, the first sub-PMOS transistor PT11 and the second sub-PMOS transistor PT12 may share the single first gate G11.

The second sub-NMOS transistor NT11 may include a second source S21 and a plurality of second drains D21. The second sub-NMOS transistors NT12 may include a second source S22 and a plurality of second drains D22. An active region ACT21 of the second sub-NMOS transistor NT11 and an active region ACT22 of the second sub-NMOS transistor NT12 may be symmetrical with respect to the first direction DR1 at an angle of about 180° to alternately arrange the second drains D22 and D21 parallel to each other. By the arrangement of the active regions ACT21 and ACT22, the second sub-NMOS transistor NT11 and the second sub-NMOS transistor NT12 may share the single second gate G21.

The first gate G11 and the second gate G21 may be electrically connected to the input signal line IN.

The first sources S11 and S12 may be electrically connected with the power voltage line VDD using at least one interconnection line Maa.

The second sources S21 and S22 may be electrically connected with the ground voltage line VSS using at least one interconnection line Mbb.

The first and second drains D11, D12, D21 and D22 may be commonly connected with the output signal line OUT using at least one interconnection line Mcc.

According to various embodiments, the sub-PMOS transistors or the sub-NMOS transistors may be meshed with each other to greatly reduce an occupying area of the inverter. For example, the PMOS transistor PT includes a first sub-PMOS transistor PT11 and a second sub-PMOS transistor PT12, and the first drains D11 of the first sub-PMOS transistor PT11 and the first drains D12 of the second sub-PMOS transistor PT12 are arranged in parallel with one another and alternately meshed with each other as shown in FIG. 13. For example, a first protrusion (i.e., a first drain D12) extending from the first source S12 is in parallel and adjacent with a first protrusion (i.e., a first drain D11) of the first source S11 and the second protrusion (i.e., a first drain D12) extending from the first source S12 is in parallel and adjacent with a second protrusion (i.e., first drain D11) of the first source S11 allowing the protrusions from the two different first sources to alternately mesh with each other as shown in FIG. 13. For example, the NMOS transistor NT includes a first sub-NMOS transistor NT11 and a second sub-NMOS transistor NT12, and the first drains D21 of the first sub-NMOS transistor NT11 and the first drains D22 of the second sub-NMOS transistor NT12 are arranged in parallel with one another and alternately meshed with each other as shown in FIG. 13. For example, a first protrusion (i.e., a second drain D22) extending from the second source S22 is in parallel and adjacent with a first protrusion (i.e., a second drain D21) of the second source S21 and the second protrusion (i.e., a second drain D22) extending from the second source S22 is in parallel and adjacent with a second protrusion (i.e., second drain D21) of the second source S21 allowing the protrusions from the two different second sources to alternately mesh with each other as shown in FIG. 13.

Further, in an embodiment, the sources making contact with the power voltage line VDD or the ground voltage line VSS may have the single finger structure to secure a constant area. The drains making contact with the output signal line OUT may have the multi finger structure. Thus, in an embodiment, the output current characteristic may be improved.

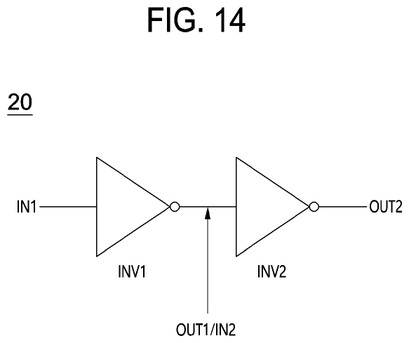

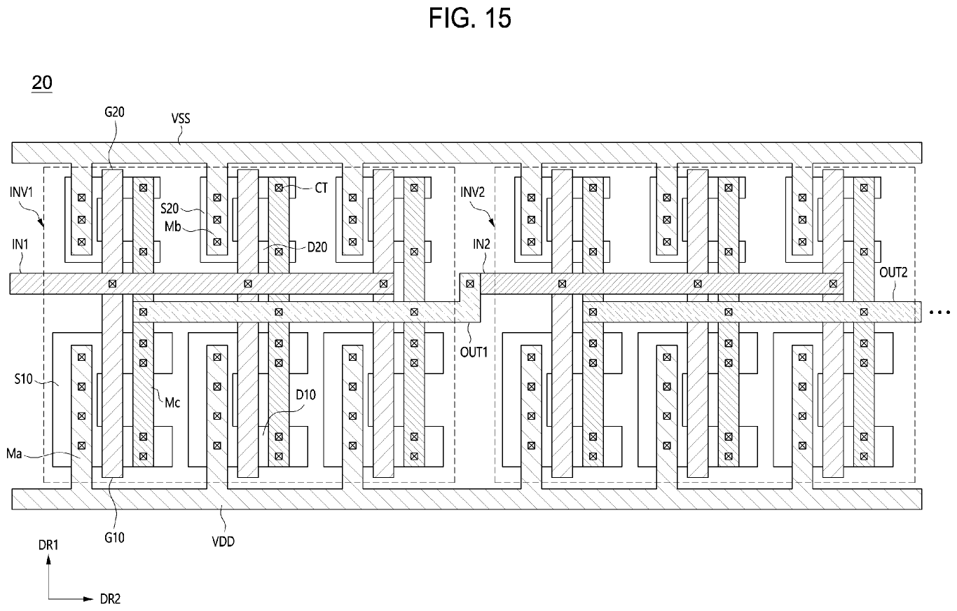

FIG. 14 is a circuit diagram illustrating a semiconductor integrated circuit device with a plurality of inverters in accordance with various embodiments and FIG. 15 is a layout illustrating the semiconductor integrated circuit device in FIG. 14.

Referring to FIG. 14, a semiconductor integrated circuit device 20 may include a plurality of inverters INV1 and INV2 serially connected with each other. The semiconductor integrated circuit device 20 may include a ring oscillator, a signal delay or a buffer circuit.

The inverters INV1 and INV2 may be serially connected with each other. For example, an output terminal of the first inverter INV1 may be connected to an input terminal of the second inverter INV2.

In various embodiments, each of the first and second inverters INV1 and INV2 of the semiconductor integrated circuit device 20 may have a structure substantially the same as the structure of the inverter 10a. Alternatively, each of the first and second inverters INV1 and INV2 may have a structure substantially the same as the structure of the inverter 10a in FIG. 3 or the inverted 10b in FIG. 13. Thus, any further illustrations with respect to the same elements may be omitted herein for brevity.

In various embodiments, a first gate G10 and a second gate G20 of the first inverter INV1 may be commonly connected to a first input signal line IN1. A first gate G10 and a second gate G20 of the second inverter INV2 may be commonly connected to a second input signal line IN2.

First drains D10 and second drains D20 of the first inverter INV1 may be commonly connected to a first output signal line OUT1. The first output signal line OUT1 may be electrically connected with the second input signal line IN2 through a contact.

First drains D10 and second drains D20 of the second inverter INV2 may be commonly connected to a second output signal line OUT2.

According to various embodiments, each of the PMOS transistor and the NMOS transistor may include the source having the single finger shape or a single pattern shape with an area and the drain having the multi finger shape or a multi pattern shape extended parallel to each other.

In an embodiment, the PMOS transistor and the NMOS transistor may include the plurality of the drains as an output node of the inverter to improve the output current characteristic.

Further, in an embodiment, the sources of the PMOS transistor and the NMOS transistor to which a power voltage and a ground voltage may be input may have an area larger than a summed area of the drains to reduce a voltage loss caused by a high contact resistance.

The above described embodiments of the present disclosure are intended to illustrate and not to limit the present disclosure. Various alternatives and equivalents are possible. The embodiments are not limited by the embodiments described herein. Nor are the embodiments limited to any specific type of semiconductor device. Another additions, subtractions, or modifications are obvious in view of the present disclosure and are intended to fall within the scope of the appended claims.

What is claimed is:

1. An inverter comprising:
at least one p-channel metal-oxide semiconductor (PMOS) transistor including a first gate connected to an input signal line, a first source connected to a power voltage line and a first drain connected to an output signal line; and
at least one n-channel metal-oxide semiconductor (NMOS) transistor including a second gate connected to the input signal line, a second source connected to a ground voltage line and a second drain connected to the output signal line,
wherein at least one of the first source and the second source has a single finger region extended in a first direction, and
wherein at least one of the first drain and the second drain has a multi finger region extending substantially parallel to each other in a second direction different from the first direction.

2. The inverter of claim 1, wherein the PMOS transistor further comprises a first active region, and the first active region comprises a first single finger region extended in the first direction and a plurality of first multi finger regions extended from a side surface of the first single finger region in the second direction.

3. The inverter of claim 2, wherein the first gate is extended at a central portion of the first active region, the first source is formed in the first single finger region at one side of the first gate, and the first drain is formed in the first multi finger regions at the other side of the first gate.

4. The inverter of claim 3, wherein the first drain has an area smaller than an area of the first source.

5. The inverter of claim 1, wherein the NMOS transistor further comprises a second active region, and the second active region comprises a second single finger region extended in the first direction and a plurality of second multi finger regions extended from a side surface of the second single finger region in the second direction.

6. The inverter of claim 5, wherein the second gate is extended at a central portion of the second active region, the second source is formed in the second single finger region at one side of the second gate, and the second drain is formed in the second multi finger regions at the other side of the second gate.

7. The inverter of claim 6, wherein the second drain has an area smaller than an area of the second source.

8. An inverter comprising:
a plurality of sub-p-channel metal-oxide semiconductor (PMOS) transistors, each of the sub-PMOS transistors including a first gate extended in a first direction, a first source positioned at one side of the first gate, and a plurality of first drains positioned at the other side of the first gate, each of the first drains extending from the first source, substantially in parallel with one another, in a second direction intersected with first direction;
a plurality of sub-n-channel metal-oxide semiconductor (NMOS) transistors, each of the sub-NMOS transistors including a second gate extended in the first direction, a second source positioned at one side of the second gate, and a plurality of second drains positioned at the other side of the second gate, each of the second drains extending from the second source, substantially in parallel with one another, in the second direction;
an input signal line commonly connected to the first gate and the second gate;
a power voltage line electrically connected to the first source;
a ground voltage line electrically connected to the second source; and
an output signal line commonly connected to the first drains and the second drains.

9. The inverter of claim 8, wherein the plurality of sub-PMOS transistors comprise a first sub-PMOS transistor and a second sub-PMOS transistor, and the first drains of the first sub-PMOS transistor and the first drains of the second sub-PMOS transistor are arranged substantially in parallel with one another and are alternately meshed with each other.

10. The inverter of claim 8, wherein the plurality of sub-NMOS transistors comprise a first sub-NMOS transistor and a second sub-NMOS transistor, and the first drains of the first sub-NMOS transistor and the first drains of the second sub-NMOS transistor are arranged substantially in parallel with one another and are alternately meshed with each other.

11. The inverter of claim 8, wherein a total area of first drains included in a sub-PMOS transistor from the plurality of sub-PMOS transistors is less than an area of a first source included in the sub-PMOS transistor from the plurality of sub-PMOS transistors.

12. The inverter of claim 8, wherein a total area of second drains included in a sub-NMOS transistor from the plurality of sub-NMOS transistors is less than an area of a second source included in the sub-NMOS transistor from the plurality of sub-NMOS transistors.

13. A semiconductor integrated circuit device comprising:
a first inverter; and
a second inverted serially connected with the first inverter,
wherein at least one first inverter and the second inverter comprises at least one p-channel metal-oxide semiconductor (PMOS) transistor and at least one n-channel metal-oxide semiconductor (NMOS) transistor,
wherein the PMOS transistor comprises:
a first gate extended in a first direction;
a first source positioned at one side of the first gate; and
a plurality of first drains positioned at the other side of the first gate, each of the first drains extending from the first source, substantially in parallel with one another, in a second direction intersected with first direction, and
wherein the NMOS transistor comprises:
a second gate extended in the first direction;
a second source positioned at one side of the second gate; and
a plurality of second drains positioned at the other side of the second gate, each of the second drains extending from the second source, substantially in parallel with one another, in the second direction.

14. The semiconductor integrated circuit device of claim 13, further comprising:
a power voltage line electrically connected to the first source; and
a ground voltage line electrically connected to the second source.

15. The semiconductor integrated circuit device of claim 13,
wherein each of the first and second inverters comprises the PMOS transistor and the NMOS transistor, and
wherein the semiconductor integrated circuit device further comprises:
a first input signal line connected to the first gate and the second gate of the first inverter to receive an input signal;
a first output signal line commonly connected to the first and second drains of the first inverter;
a second input signal line connected to the first and second gate of the second inverter and connected to the first input signal line; and
a second output signal line commonly connected to the first and second drains of the second inverter.

16. The semiconductor integrated circuit device of claim 13, wherein a total area of the first drains is less than an area of the first source.

17. The semiconductor integrated circuit device of claim 13, wherein a total area of the second drains is less than an area of the second source.
